(19) United States
(12) Patent Application Publication
(10) Pub. No.: US 2007/0048981 A1
(43) Pub. Date: Mar. 1, 2007

(54) METHOD FOR PROTECTING A SEMICONDUCTOR DEVICE FROM CARBON DEPLETION BASED DAMAGE

(75) Inventors: Griselda Bonilla, Fishkill, NY (US); Richard A. Conti, Katonach, NY (US); Timothy J. Dalton, Ridgefield, CT (US); Nicholas C. M. Fuller, Ossining, NY (US); Kelly Malone, Poughkeepsie, NY (US); Satyanarayana V. Nitta, Poughquag, NY (US); Shom Ponoth, Fishkill, NY (US)

Correspondence Address: CANTOR COLBURN LLP - IBM FISHKILL, 55 GRIFFIN ROAD SOUTH, BLOOMFIELD, CT, 06002, US

(73) Assignee: INTERNATIONAL BUSINESS MACHINES CORPORATION, ARMONK, NY (US)

(21) Appl. No.: 11/162,219

(22) Filed: Sep. 1, 2005

(51) Int. Cl. H01L 21/04

(52) U.S. Cl. 438/510

(57) ABSTRACT

A method for protecting a semiconductor device from carbon depletion type damage includes enriching an exposed surface of a porous interlevel dielectric material (ILD) with a carbon based material, and implementing a plasma based operation on the porous ILD material. The enriching of the porous ILD material reduces effects of carbon depletion as a result of the plasma based operation.

### BACKGROUND

The present invention relates generally to semiconductor device manufacturing, and, more particularly, to a method for protecting a semiconductor device from carbon depletion based damage.

In the fabrication of integrated circuit devices, it is often desirable to isolate individual components of the integrated circuits from one another with insulative materials. Such insulative materials may include, for example, silicon dioxide, silicon nitride and silicon carbide. While these materials may have acceptable insulating properties in many applications, they also have relatively high dielectric constants, which can lead to capacitive coupling between proximate conductive elements. This is particularly disadvantageous, given the ever-decreasing distances between conductive circuit elements, and the use of multi-layered structures. An unnecessary capacitive coupling between adjacent wires increases the RC time delay of a signal propagated therethrough, resulting in decreased device performance.

Thus, for specific applications, insulating materials having relatively low dielectric constants (e.g., k<3) are desired. In very large scale integrated circuit (VLSI) technology, silicon dioxide (SiO₂) has been traditionally used as an interlevel dielectric (ILD) material in conjunction with aluminum interconnect material. More recently, however, significant advancements have been made to enhance circuit performance by replacing the SiO₂ with a “low-k” porous dielectric and by using copper (higher conductivity) interconnect.

One drawback with using porous ILD and IMD (intermetal dielectric) materials in back end of line (BEOL) processing is the damage sustained by the material as a result of various plasma exposure steps (e.g., reactive ion etching (RIE) and stripping). In one respect, this damage is characterized by a gradient in carbon concentration through the depth of the ILD/IMD material wherein the carbon concentration is reduced near the lines and increases down through the bulk of the ILD/IMD material. Historically, upon exposure to plasma processing, denser ILD materials have a carbon depletion layer of less than about 10 nm, and hence are less susceptible to plasma damage. In contrast, the carbon depletion layer for various ultra low-k ILD materials can now extend to depths of up to about 65 nm, which will adversely affect the integrity of the ILD/IMD, thereby increasing leakage current and capacitance.

An existing technique for addressing this problem with regard to porous ILD/IMD materials has been to form thin, dense hardmask films (e.g., about 50 nm in thickness) as a protective layer over the ILD/IMD layers. However, if oxygen is present during the hardmask deposition process, this will have an adverse effect on the overall effective dielectric constant (k_{eff}) of the integrated build due to the fact that the dense hardmask film deposition processes can also cause damage to the ILD/IMD layer.

In other words, while attempting to protect the ILD film by first depositing a thin, dense hardmask, it is also possible to create a carbon depletion region at the hardmask/ILD interface in so doing. Thus, to reduce the k_{eff} of the device, the hardmask is then reduced to a minimal thickness or subsequently removed during chemical mechanical polishing (CMP). On the other hand, while removing the hardmask lowers the device k_{eff}, the original difficulty sought to be prevented (i.e., the susceptibility of exposed porous ILD film to plasma damage during a precleaning process) once again becomes problematic.

Accordingly, it would be desirable to be able to adequately protect a semiconductor device from carbon depletion type damage in a manner that does not adversely affect other beneficial device properties, such as low k_{eff}.

### SUMMARY

The foregoing discussed drawbacks and deficiencies of the prior art are overcome or alleviated by a method for protecting a semiconductor device from carbon depletion type damage. In an exemplary embodiment, the method includes enriching an exposed surface of a porous interlevel dielectric material (ILD) with a carbon based material, and implementing a plasma based operation on the porous ILD material. The enriching of the porous ILD material reduces effects of carbon depletion as a result of the plasma based operation.

In another embodiment, a method for forming a semiconductor device includes forming a porous interlevel dielectric (ILD) layer over a lower capping layer, forming one or more metal structures within the porous ILD layer, and removing one or more hardmask layers used in the formation of the one or more metal structures so as to expose the porous ILD layer. An exposed surface of the porous ILD layer is enriched with a carbon based material, and a cleaning operation is implemented to remove oxide materials from exposed surfaces of the one or more metal structures, wherein the enriching of the porous ILD layer reduces effects of carbon depletion as a result of the cleaning operation.

### BRIEF DESCRIPTION OF THE DRAWINGS

Referring to the exemplary drawings wherein like elements are numbered alike in the several Figures:

FIGS. 1(a) through 1(f) illustrate a conventional cleaning sequence of a semiconductor device, following metal formation within an interlevel dielectric layer, in preparation for capping and formation of subsequent ILD/wiring levels;

FIGS. 2(a) through 2(f) illustrate a method for protecting a semiconductor device from carbon depletion type damage, in accordance with an embodiment of the invention;

FIGS. 3(a) and 3(b) illustrate an alternative embodiment for implementing the carbon enrichment operation and ammonia plasma clean;

FIGS. 4(a) through 4(d) illustrated still an alternative embodiment for implementing the carbon enrichment operation and ammonia plasma clean; and

FIGS. 5(a) through 5(d) illustrate an alternative embodiment of a method for protecting a semiconductor device from carbon depletion type damage, implemented prior to hardmask formation.

### DETAILED DESCRIPTION

Disclosed herein is a method for protecting a semiconductor device from carbon depletion type damage, such as may be sustained during a plasma based operation such as a hardmask deposition or cleaning (pretreatment) operation for example. Briefly stated, an exposed surface (e.g., low-K ILD post deposition, copper, low-k material) is enriched with carbon prior to a plasma based operation (e.g., hardmask deposition, cleaning operation) of the exposed surface, thereby reducing the degree of carbon depletion in the surface as a result of the plasma based operation. Alternatively, the carbon enriching may be implemented subsequently to, simultaneously with, or in lieu of a more conventional pretreatment operation such as ammonia plasma cleaning, which prepares the device for the deposition of a subsequent capping layer and next interlevel dielectric layer.

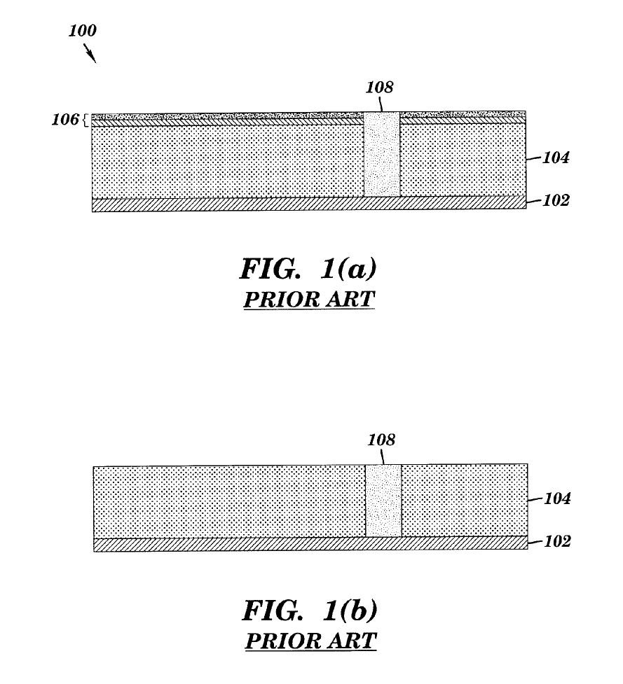

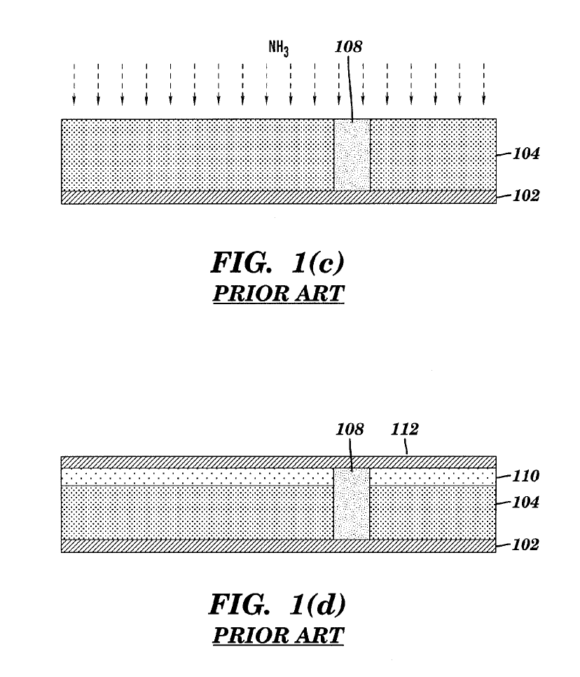

Referring initially to FIGS. 1(a) through 1(d), there is shown a series of process flow diagrams illustrating a conventional cleaning sequence of a semiconductor device, following metal formation within an interlevel dielectric layer, in preparation for capping and formation of subsequent ILD/wiring levels. As shown in FIG. 1(a), the portion of the semiconductor device 100 illustrated includes a lower capping layer 102 that protects lower device levels (not shown), such as an interlevel dielectric layers, wiring, and/or front end of line (FEOL) structures, such as diffusion regions, gates and substrate surfaces, for example. A porous, ultra low-k interlevel dielectric layer 104 is formed upon the lower capping layer 102 (e.g., NBLoK™ from Applied Materials). Examples of such porous low-k materials may include, for example, SiCOH, as is described in U.S. Pat. No. 6,768,200, assigned to the assignee of the present application and the contents of which are incorporated herein in their entirety.

Prior to metal formation within the porous ILD 104, a hardmask 106 is patterned such that the porous ILD 104 may be properly etched and the metal fill 108 introduced into the openings formed therein. The hardmask 106 may be a single layer or a dual hardmask (e.g., tetraethoxysilane (TEOS)/octamethyltrisiloxane (OMCTS)), as shown in the figure. As will be appreciated, the metal fill may be implemented in accordance with single damascene processing (i.e., separate via and line formation) or dual damascene processing (i.e., simultaneous via and line formation). As illustrated in FIG. 1(b), the hardmask 106 is then removed by CMP, thereby exposing the porous ILD layer 104 and metal fill 108. At this point during conventional processing, a precleaning step for removing copper oxide from the copper surfaces (fill 108) is carried out in order to prepare the device for the formation of the next capping layer.

Then, as shown in FIG. 1(c), a plasma ammonia based process (for example) is used to successfully clean the surface of the metal fill 108 by reducing the oxide material thereon. While the Figures illustrate NH₃ as an exemplary plasma based cleaning material, it will be appreciated that other types of plasma processes (such as a hydrogen based plasma process) could also be used a cleaning agent for the oxide materials. In any case, as indicated above, the use of the plasma (NH₃, H₂, etc.) causes the depletion in carbon concentration of the porous ILD layer 104 to a depth of several hundred angstroms. This carbon-depleted portion (which increases the effective dielectric constant of ILD 104) is illustrated at the upper region 110 of the ILD layer 104 in FIG. 1(d), over which the next capping layer 110 is formed.

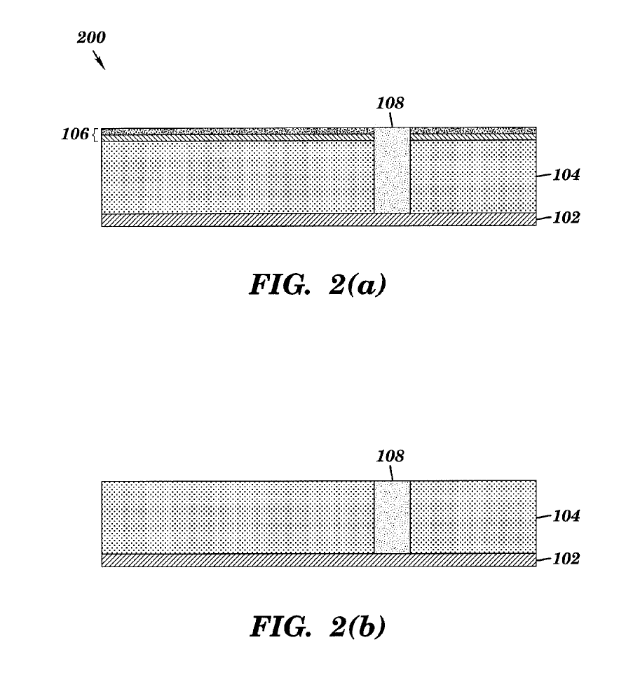

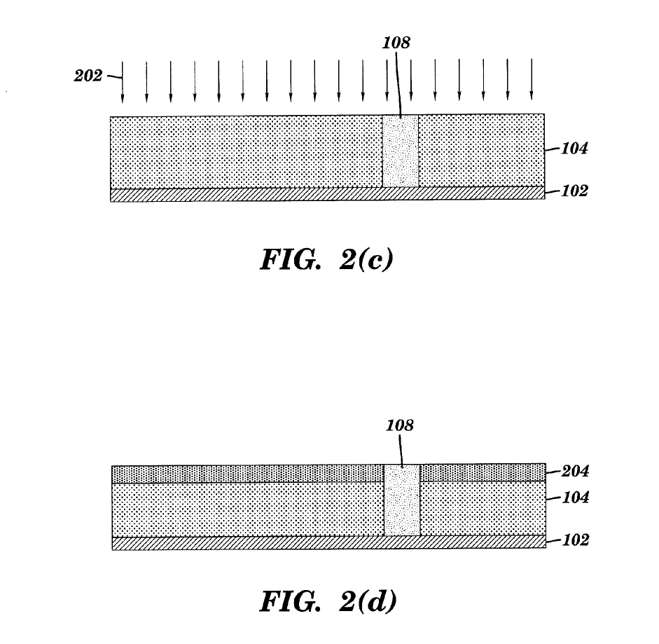

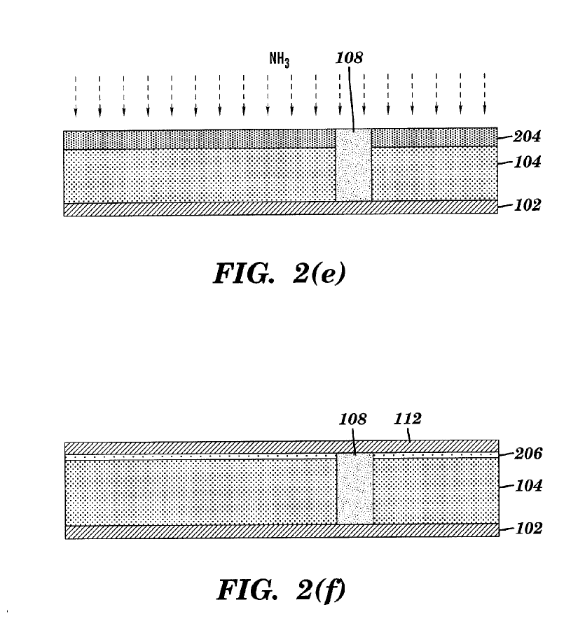

Therefore, in accordance with an embodiment of the invention, FIGS. 2(a) through 2(f) illustrate a method for protecting a semiconductor device 200 from carbon depletion type damage. The formation of the metal fill 108 (e.g., copper) within the lower level, ultra low-k porous dielectric layer 104 in FIGS. 2(a) and 2(b) is similar to that depicted in FIGS. 1(a) and 1(b). However, in preparation for a cleaning pretreatment step prior to cap formation, FIG. 2(c) illustrates a carbon enrichment operation (indicated by arrows 202) so as to avoid excessive carbon depletion during the preclean.

More specifically, the carbon enrichment operation may include, in one embodiment, silylation of the exposed ILD 104 and metal 108 with silylation agents having —Si—R functionalities (e.g., methyl terminated alkoxy, acetoxy, amino, or chloro silane reagents). Alternatively, the enrichment operation may include exposure to a plasma containing low pressure hydrocarbon species such as CₓH_{y}, wherein the species may be an alkane, alkene or alkyne. In order to facilitate breaking of the C—H bond, an alkane species may be used so that carbon is more easily introduced to the plasma ambient. This consumes excess hydrogen (from the NH₃ or H₂ pre-cleaning gas) that would otherwise chemically alter SiCOH film, thereby providing a path for CO or CO₂ and OH or H₂O formation (and perhaps additional COH complexes), facilitating the reduction of copper oxide to copper and replacing any carbon depleted from the SiCOH ILD with carbon from the hydrocarbon co-reactant. However, for this process to be efficient, the effective carbon concentration in the plasma must be above a specific threshold to enable complete CuO reduction and still provide sufficient carbon species that can be incorporated into the film. On the other hand, the use of an alkene or alkyne would provide a higher carbon to hydrogen ratio in order to maximize the replenishment of carbon lost from the SiCOH.

Regardless of the specific type of carbon enrichment operation implemented, FIG. 2(d) illustrates an enriched carbon portion 204 of the porous ILD layer 104. Therefore, after the reducing ammonia plasma is introduced in FIG. 2(e), the extent of the resulting carbon depletion region 206 shown in FIG. 2(f) in the porous is much less than in the case of FIG. 1(d).

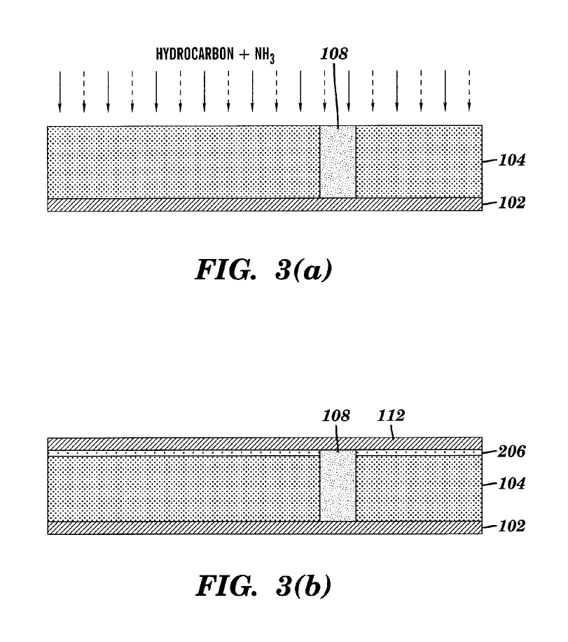

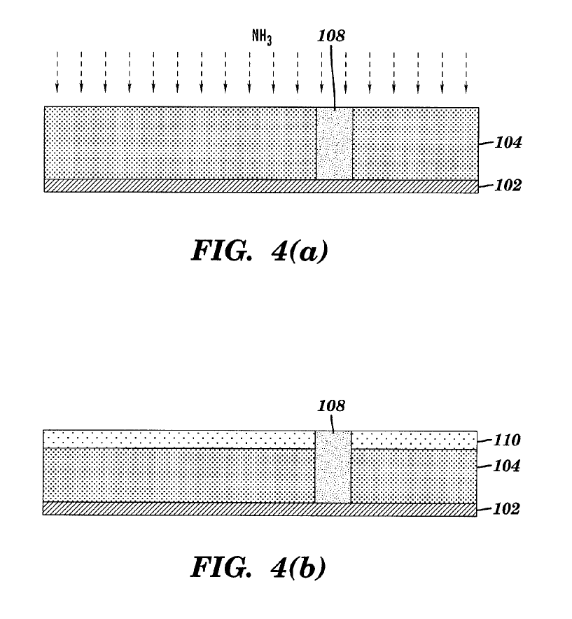

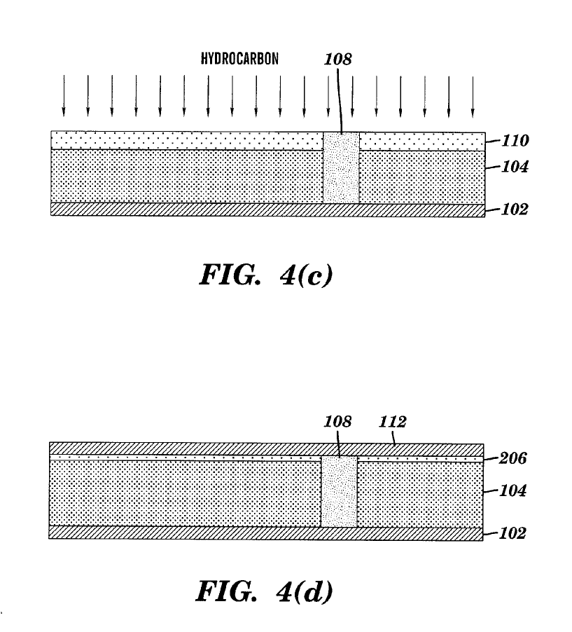

As indicated above, the carbon enrichment operation need not necessarily be performed prior to the plasma clean operation. For example, the carbon enrichment operation and plasma clean may be implemented in a single step by introduction of a hydrocarbon species into the ammonia (or hydrogen) plasma as depicted in FIGS. 3(a) and 3(b). In this embodiment, the free carbon reacts with hydrogen from the ammonia to avoid carbon depletion of the SiCOH ILD 106 or to provide a source of carbon that can replenish the carbon removed from the SiCOH. In still another embodiment depicted in FIGS. 4(a) through 4(d), the ammonia plasma clean step can be followed by the carbon enrichment operation to replenish the carbon removed from the SiCOH during the ammonia treatment. It is still further contemplated that the plasma treatment may be eliminated entirely by implementing a hydrocarbon enrichment step to both reduce the copper oxide and maintain a source of carbon for the SiCOH, ultra low-k ILD layer.

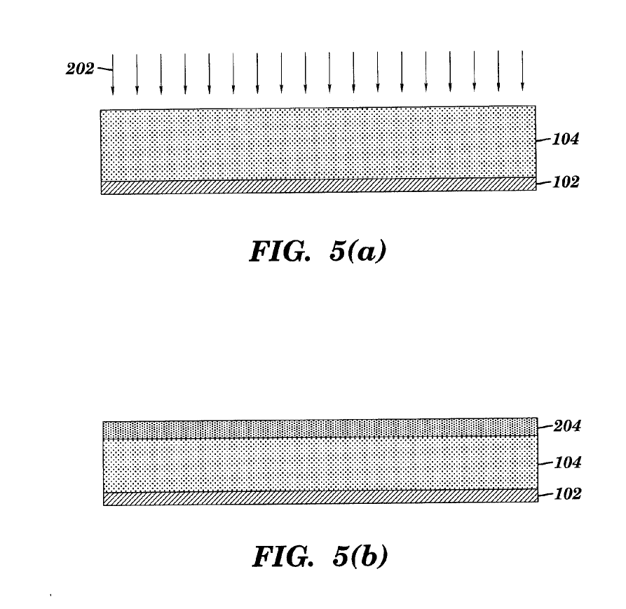

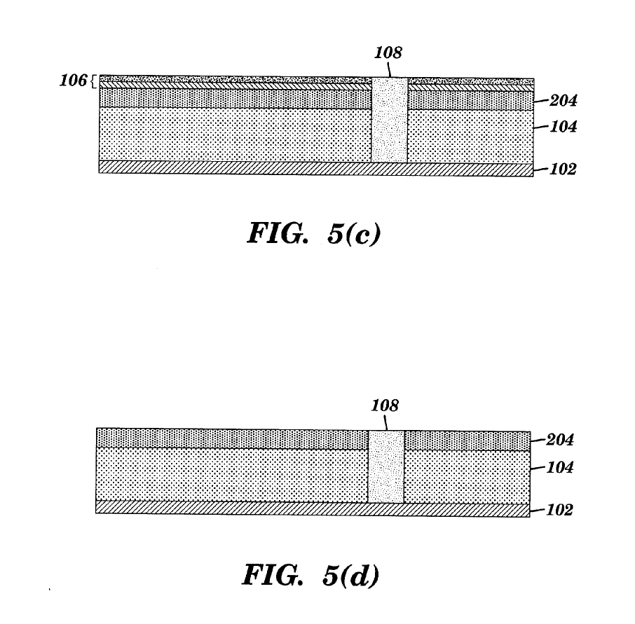

Finally, FIGS. 5(a) though 5(d) illustrate an alternative embodiment of a method for protecting a semiconductor device from carbon depletion type damage, implemented prior to hardmask formation. As stated previously, in addition to ammonia (or hydrogen) plasma, certain hardmask formation processes can also subject a porous ILD layer 104 to carbon depletion. Thus, as shown in FIG. 5(a), the newly formed ILD layer 104 is subjected to a carbon enrichment operation (indicated by arrows 202) prior to any hardmask deposition, etching or metal formation within the ILD layer 104.

The resulting enriched carbon portion 204 of the porous ILD layer 104 is shown in FIG. 5(b). When the hardmask layer 106 is subsequently formed, patterned and the metal fill 108 deposited as shown in FIG. 5(c), the enriched carbon portion 204 provides a measure of protection against carbon depletion of the porous ILD layer 104. Following the removal of the hardmask 106 as shown in FIG. 5(d), an ammonia plasma clean operation can then take place. Should the enriched carbon portion 204 become somewhat depleted as a result of the hardmask formation, it will be appreciated that another carbon enrichment operation may be carried out prior to, subsequent to, along with, or in lieu of the plasma clean, as described in any of the embodiments above.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for protecting a semiconductor device from carbon depletion type damage, the method comprising:
enriching an exposed surface of a porous interlevel dielectric material (ILD) with a carbon based material; and
implementing a plasma based operation on said porous ILD material;
wherein said enriching said porous ILD material reduces effects of carbon depletion as a result of said plasma based operation.

2. The method of claim 1, wherein said plasma based operation comprises a cleaning operation to remove oxide materials from exposed surfaces of one or more metal structures formed within said porous ILD layer.

3. The method of claim 2, wherein said cleaning operation comprises introduction of an ammonia containing plasma to said porous ILD material and said one or more metal structures.

4. The method of claim 3, wherein said cleaning operation comprises introduction of a hydrogen containing plasma to said porous ILD material and said one or more metal structures.

5. The method of claim 3, wherein said porous ILD material comprises SiCOH.

6. The method of claim 5, wherein said enriching said porous ILD material further comprises exposure of said porous ILD material to a plasma containing, low pressure hydrocarbon species of the type CₓH_{y}.

7. The method of claim 6, wherein said hydrocarbon species further comprises one or more of: an alkane, an alkene, and an alkyne.

8. The method of claim 5, wherein said enriching said porous ILD material further comprises exposure of said porous ILD material to a silylation process.

9. The method of claim 8, wherein said silylation process further comprises reacting the surface of said porous ILD materials with one of a methyl terminated alkoxy, acetoxy, amino, and chloro silane reagent.

10. The method of claim 5, wherein said cleaning operation is implemented subsequent to said enriching said porous ILD material.

11. The method of claim 5, wherein said cleaning operation is implemented prior to said enriching said porous ILD material.

12. The method of claim 5, wherein said cleaning operation is implemented concurrently with said enriching said porous ILD material.

13. The method of claim 1, wherein said enriching said porous ILD material also serves as a cleaning operation to remove oxide materials from exposed surfaces of one or more metal structures formed within said porous ILD layer.

14. The method of claim 1, wherein said plasma based operation further comprises a hardmask deposition on said porous ILD layer.

15. A method for forming a semiconductor device, the method comprising:
forming a porous interlevel dielectric (ILD) layer over a lower capping layer;
forming one or more metal structures within said porous ILD layer;
removing one or more hardmask layers used in the formation of said one or more metal structures so as to expose said porous ILD layer;
enriching an exposed surface of said porous ILD layer with a carbon based material; and
implementing a cleaning operation to remove oxide materials from exposed surfaces of said one or more metal structures;
wherein said enriching said porous ILD layer reduces effects of carbon depletion as a result of said cleaning operation.

16. The method of claim 15, wherein said cleaning operation comprises introduction of an ammonia containing plasma to said porous ILD layer and said one or more metal structures.

17. The method of claim 15, wherein said cleaning operation comprises introduction of an ammonia containing plasma to said porous ILD layer and said one or more metal structures.

18. The method of claim 16, wherein said porous ILD layer comprises SiCOH.

19. The method of claim 18, wherein said enriching said porous ILD layer further comprises exposure of said porous ILD layer to a plasma containing, low pressure hydrocarbon species of the type CₓH_{y}.

20. The method of claim 19, wherein said hydrocarbon species further comprises one or more of: an alkane, an alkene, and an alkyne.

21. The method of claim 18, wherein said enriching said porous ILD material further comprises exposure of said porous ILD material to a silylation process.

22. The method of claim 21, wherein said silylation process further comprises reacting the surface of said porous ILD materials with one of a methyl terminated alkoxy, acetoxy, amino, and chloro silane reagent.

23. The method of claim 18, wherein said cleaning operation is implemented subsequent to said enriching said porous ILD layer.

24. The method of claim 18, wherein said cleaning operation is implemented prior to said enriching said porous ILD layer.

25. The method of claim 18, wherein said cleaning operation is implemented concurrently with said enriching said porous ILD layer.

26. The method of claim 15, wherein said enriching said porous ILD layer also serves as said cleaning operation.
